(19) United States
(12) Patent Application Publication
(10) Pub. No.: US 2025/0386685 A1
(43) Pub. Date: Dec. 18, 2025

(54) DISPLAY DEVICE, DISPLAY PANEL AND MANUFACTURING METHOD THEREFOR

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Xiaoqi DING, Beijing (CN); Li JIA, Beijing (CN); Tao GAO, Beijing (CN); Yuanzheng GUO, Beijing (CN); Liqiang CHEN, Beijing (CN); Xinlei YANG, Beijing (CN)

(21) Appl. No.: 18/877,289

(22) PCT Filed: Sep. 22, 2022
(86) PCT No.: PCT/CN2022/120509

§ 371 Date: Dec. 20, 2024

(51) Int. Cl. H10K 59/131; H10K 59/12; H10K 59/124

(52) U.S. Cl. CPC H10K 59/131; H10K 59/1201; H10K 59/124

(57) ABSTRACT

A display device, a display panel and a manufacturing method, relating to the technical field of display. The display panel has a display area (AA), a peripheral area (WA), and a lead-out area (FA), and the lead-out area (FA) comprises a binding part (PA); the display panel comprises a substrate (SU), a circuit layer (DL), and a plurality of light-emitting devices (LD). The substrate (SU) is provided with a transfer line (CL) and a substrate transfer hole (SH) exposing the transfer line (CL), and the transfer line (CL) passes through the peripheral area (WA) and extends to the lead-out area (FA); at least one of the peripheral area (WA) and the display area (AA) is provided with the substrate transfer hole (SH).

### CROSS REFERENCE

The present application is a national phase application of International Application No. PCT/CN2022/120509, filed on Sep. 22, 2022, and the entire contents thereof are incorporated herein by reference.

### TECHNICAL FIELD

The present disclosure relates to the field of display technology, and in particular, to a display device, a display panel, and a method for manufacturing display panel.

### BACKGROUND

Display panels have been used in mobile phones, tablet computers, televisions and other terminal devices. The display panels using organic light emitting diodes (OLEDs) are widely used.

It should be noted that the information disclosed in the above background technology section is only used to enhance the understanding of the background of the present disclosure, and therefore may include information that does not constitute the prior art known to those ordinary skilled in the art.

### SUMMARY

A display device, a display panel and a method for manufacturing the display panel.

According to one aspect of the present disclosure, a display panel is provided, including a display area, a peripheral area outside the display area, and a lead-out area outside the peripheral area; and the display panel including:
a substrate, including a transfer line and a substrate transfer hole exposing the transfer line, wherein the transfer line is extended to the lead-out area through the peripheral area; at least one of the peripheral area and the display area is provided with the substrate transfer hole;
a circuit layer, disposed on a side of the substrate and includes a circuit transfer hole connected to the substrate transfer hole, and an orthographic projection of a side wall of the circuit transfer hole on the substrate is located outside a side wall of the substrate transfer hole connected to the circuit transfer hole; the circuit layer includes a signal line, and at least part of the signal line is extended to the circuit transfer hole and the substrate transfer hole, and is connected to the transfer line; and
a plurality of light emitting devices, disposed on a side of the circuit layer away from the substrate and located in the display area.

In an exemplary implementation of the present disclosure, the substrate includes:
a first substrate, wherein the transfer line is disposed on a side of the first substrate; and
a second substrate, disposed on a side of the transfer line away from the first substrate; the substrate transfer hole is disposed in the second substrate; and the circuit layer is disposed on a side of the second substrate away from the first substrate.

In an exemplary implementation of the present disclosure, the circuit layer includes an opening layer and a filling layer stacked in sequence in a direction away from the first substrate, the circuit transfer hole is formed through the opening layer; and the filling layer includes at least part of the signal line.

In an exemplary implementation of the present disclosure, the opening layer includes a circuit blocking layer, a buffer layer, a semiconductor layer, a first gate insulating layer, a first gate electrode layer and a second gate insulating layer stacked in sequence in a direction away from the first substrate;
the filling layer includes a second gate layer, an interlayer dielectric layer, a first source-drain layer, a passivation layer, a first planar layer, a second source-drain layer, and a second planar layer stacked in sequence in a direction away from the first substrate; the interlayer dielectric layer and the passivation layer are recessed at the circuit transfer hole, and a recessed area is filled with the first planar layer;
the circuit transfer hole is formed through the circuit blocking layer, the buffer layer, the first gate insulating layer and the second gate insulating layer; and the second gate layer includes at least a portion of the signal line.

In an exemplary implementation of the present disclosure, the substrate transfer hole includes a plurality of substrate hole segments penetrating along a thickness direction of the substrate; and
in two adjacent substrate hole segments, a side wall of the substrate hole segment close to the circuit layer is located outside a side wall of the substrate hole segment away from the circuit layer.

In an exemplary implementation of the present disclosure, a number of the substrate hole segments is two, and depths of the two substrate hole segments are same.

In an exemplary implementation of the present disclosure, a side wall of the circuit transfer hole is a slope surface expanding in a direction away from the substrate.

In an exemplary implementation of the present disclosure, the circuit transfer hole includes a plurality of circuit hole segments penetrating along a thickness direction of the substrate; and
in two adjacent circuit hole segments, a side wall of the circuit hole segment away from the substrate is located outside a side wall of the circuit hole segment close to the substrate.

In an exemplary implementation of the present disclosure, the circuit layer further includes a connecting lead extending from the display area to the peripheral area, and the connecting lead is located between at least a portion of the signal line and the substrate; and
an end of the connecting lead located in the peripheral area is connected to at least a portion of the transfer line through the circuit transfer hole and the substrate transfer hole that are connected to each other, and an end of the connecting lead located in the display area is connected to at least a portion of the signal line through the display transfer hole located in the display area.

In an exemplary implementation of the present disclosure, the signal line connected to the connecting lead is located in the first source-drain layer, and the connecting lead is located in the second gate layer; and
the display transfer hole is formed through the first planar layer and the passivation layer.

According to an aspect of the present disclosure, a manufacturing method of a display panel id provided, the display panel including a display area, a peripheral area outside the display area, and a lead-out area outside the peripheral area; the manufacturing method including:
forming a substrate including a transfer line, wherein the transfer line is extended to the lead-out area through the peripheral area;
forming an opening layer on a side of the substrate;
forming a circuit transfer hole in the opening layer, and forming in the substrate a substrate transfer hole exposing the transfer line, wherein the circuit transfer hole is connected to the substrate transfer hole; the circuit transfer hole is located in at least one of the peripheral area and the display area; and an orthographic projection of a side wall of the circuit transfer hole on the substrate is located at an inner side of a side wall of the substrate transfer hole connected to the circuit transfer hole;
enlarging the circuit transfer hole so that the side wall of the substrate transfer hole is within a range encircled by the orthographic projection on the substrate of the side wall of the circuit transfer hole connected to the circuit transfer hole;
forming a filling layer covering the opening layer and filling the circuit transfer hole and the substrate transfer hole; the filling layer including a signal line extending into the circuit transfer hole and the substrate transfer hole and connected to the transfer line; and
forming a plurality of light emitting devices in the display area on a side of the filling layer away from the substrate.

In an exemplary implementation of the present disclosure, the forming the substrate including the transfer line includes:
forming a first substrate;
forming the transfer line on a side of the first substrate; and
forming a second substrate on a side of the transfer line away from the first substrate.

In an exemplary implementation of the present disclosure, the forming the circuit transfer hole in the opening layer, and forming in the substrate the substrate transfer hole exposing the transfer line, wherein the circuit transfer hole is connected to the substrate transfer hole includes:
forming the circuit transfer hole in the opening layer; wherein the circuit transfer hole is located in at least one of the peripheral area and the display area; and
etching, using the opening layer as mask, the substrate along the circuit transfer hole to form the substrate transfer hole exposing the transfer line; wherein the orthographic projection of the side wall of the circuit transfer hole on the substrate is located on the inner side of the side wall of the substrate transfer hole connected to the circuit transfer hole.

In an exemplary implementation of the present disclosure, the enlarging the circuit transfer hole includes:
forming an etching resist layer covering the opening layer and filling the circuit transfer hole and the substrate transfer hole;
forming an annular hole in the etching resist layer to expose the opening layer, wherein a portion of the etching resist layer surrounded by the annular hole is filled in the circuit transfer hole and the substrate transfer hole; and the side wall of the substrate transfer hole is located within a range encircled by an orthographic projection of an outer wall of the annular hole on the substrate;
etching the opening layer exposed by the annular hole so that the side wall of the substrate transfer hole is located within the orthographic projection on the substrate of the side wall of the circuit transfer hole connected to the substrate transfer hole; and removing the etching resist layer.

In an exemplary implementation of the present disclosure, the forming the opening layer on the side of the substrate includes:
stacking, sequentially on a side of the second substrate away from the first substrate, a circuit blocking layer, a buffer layer, a semiconductor layer, a first gate insulating layer, a first gate layer, and a second gate insulating layer;
the forming the filing layer covering the opening layer and filling the circuit transfer hole and the substrate transfer hole includes:
stacking, sequentially on a side of the opening layer away from the first substrate, a second gate layer, an interlayer dielectric layer, a first source-drain layer and a passivation layer, wherein the interlayer dielectric layer and the passivation layer are recessed at the circuit transfer hole; and the second gate layer includes the signal line extending into the circuit transfer hole and the substrate transfer hole and connected to the transfer line;
forming a first planar layer covering the passivation layer and filling the recessed area of the interlayer dielectric layer and the passivation layer; and
stacking, sequentially on a side of the first planar layer away from the first substrate, a second source-drain layer and a second planar layer.

In an exemplary implementation of the present disclosure, the etching the substrate along the circuit transfer hole to form the substrate transfer hole exposing the transfer line includes:
etching the substrate multiple times along the circuit transfer hole so that the substrate transfer hole includes a plurality of substrate hole segments penetrating along a thickness direction of the substrate; in two adjacent substrate hole segments, a side wall of the substrate hole segment close to the opening layer is located outside a side wall of the substrate hole segment away from the opening layer.

In an exemplary implementation of the present disclosure, the etching the substrate multiple times along the circuit transfer hole includes:
etching, by a dry etching process, the substrate multiple times along the circuit transfer hole, and wherein the transfer line is exposed during a first time etching, and a depth of a subsequent etching is less than a depth of a previous etching.

In an exemplary implementation of the present disclosure, the substrate is etched twice, and the depth of the subsequent etching is half of the depth of the previous etching.

In an exemplary implementation of the present disclosure, the sidewall of the circuit transfer hole is a slope surface expanding in a direction away from the substrate.

According to an aspect of the present disclosure, a display device is provided, including any one of the above the display panel.

It is to be understood that the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. Obviously, the accompanying drawings described below are only some embodiments of the present disclosure, and for ordinary skilled in the art, other accompanying drawings can be obtained based on these accompanying drawings without creative effort.

FIG. 1 is a top view of an embodiment of a display panel of the present disclosure.

FIG. 2 is a top view of another embodiment of the display panel of the present disclosure.

FIG. 3 is a partial cross-sectional view of a first embodiment of the display panel of the present disclosure.

FIG. 4 to FIG. 10 are schematic diagrams corresponding to the steps of a manufacturing method of a first type of implementation.

FIG. 11 is a partial cross-sectional view of a second embodiment of the display panel disclosed herein.

FIG. 12 is a partial cross-sectional view of a third embodiment of the display panel disclosed herein.

FIG. 13 is a partial cross-sectional view of a fourth embodiment of the display panel disclosed herein.

FIG. 14 is a partial cross-sectional view of another first type of implementation of the display panel disclosed herein.

FIG. 15 to FIG. 19 are schematic diagrams corresponding to the steps of the manufacturing method of another first type of implementation.

FIG. 20 to FIG. 22 are schematic diagrams of three third types of implementations, respectively.

FIG. 23 is an electron microscope image corresponding to step S1430 of the manufacturing method of the first type of implementation.

FIG. 24 is an electron microscope image corresponding to step S1440 of the manufacturing method of the first type of implementation.

### DETAILED DESCRIPTION

Example embodiments will now be described more fully with reference to the accompanying drawings. However, example embodiments can be implemented in a variety of forms and should not be construed as limited to the embodiments set forth herein; rather, these embodiments are provided so that the present disclosure will be comprehensive and complete and fully convey the concepts of the example embodiments to those skilled in the art. The same reference numerals in the figures represent the same or similar structures, and thus their detailed description will be omitted. In addition, the drawings are only schematic illustrations of the present disclosure and are not necessarily drawn to scale.

The terms “a”, “an”, “the”, “said” and “at least one” are used to indicate the presence of one or more elements/components/etc.; the terms “including” and “having” are used to express an open-ended inclusive meaning and mean that additional elements/components/etc. may exist in addition to the listed elements/components/etc.; the terms “first”, “second” and “third” etc. are used merely as labels and are not intended to limit the quantity of their objects.

The row direction and the column direction Y in this disclosure are just two mutually perpendicular directions. In the drawings of the present disclosure, the row direction can be horizontal and the column direction Y can be vertical, but it is not limited to this. If the display panel is rotated, the actual directions of the row direction and the column direction Y may change.

In this disclosure, “overlapping” of feature A and feature B means that the orthographic projection of feature A on the substrate and the orthographic projection of feature B on the substrate at least partially overlap.

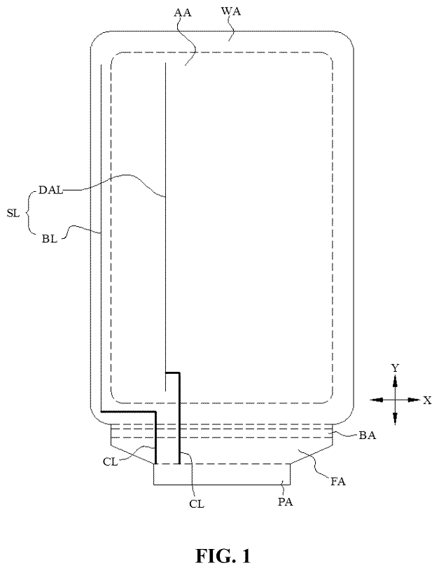

The embodiment of the present disclosure provides a display panel, as shown in FIG. 1, the display panel of the present disclosure has a display area AA, a peripheral area WA and a lead-out area FA, wherein:

The display area AA is a light-emitting area for displaying images. The peripheral area WA is located outside the display area AA. For example, the peripheral area WA can be a continuous or discontinuous annular area surrounding the display area AA, or can be a semi-enclosed area such as a “U” shape. The shape of the peripheral area WA is not particularly limited.

The lead-out area FA is located outside the peripheral area WA and can extend in the direction away from the display area AA along the column direction Y. The lead-out area FA can have a binding portion PA, and the binding portion PA has a plurality of pins. At least part of the pins of the binding portion PA can be connected to a flexible circuit board, and the flexible circuit board can be bound to a control circuit board, so as to realize the connection between the display panel and the control circuit board, and the display panel can be controlled to display images through the control circuit board. Of course, the lead-out area FA can be connected to a driver chip, which can be used to control the display panel to display images and realize touch functions, etc.

In some embodiments of the present disclosure, the lead-out area FA may include a bending area BA, which is a bendable flexible structure, and the binding portion PA is located on a side of the bending area BA away from the display area AA and between the peripheral area WA and the binding portion PA. By bending the bending area BA, the lead-out area FA can be bent to the backlight side of the display panel, that is, the side opposite to the light emitting direction. Thus, the flexible circuit board can be connected to the control circuit board on the backlight side of the display panel.

Of course, in other embodiments of the present disclosure, the lead-out area FA may not be provided with the bending area BA, and the flexible circuit board may be connected to the control circuit board on the backlight side of the display panel by bending the flexible circuit board.

It should be noted that the above-mentioned divisions of the display panel into the display area AA, the peripheral area WA, the bending area BA and the lead-out area FA are divisions based on their functions, but do not limit the physical boundaries in the display panel for realizing the divisions.

Hereinafter, each film layer of the display panel is described in detail based on the above divisions.

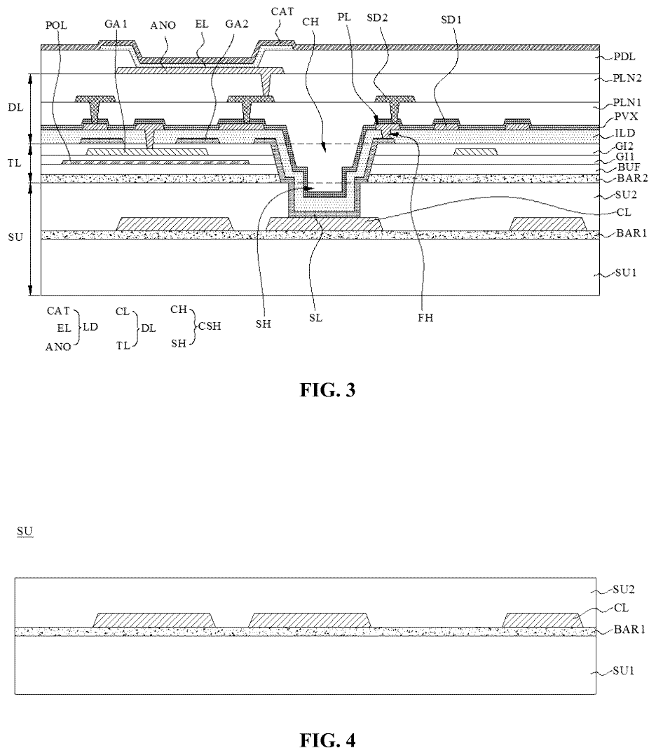

As shown in FIG. 3 and FIG. 11 to FIG. 14, the display panel may include a substrate SU and a circuit layer DL and a light emitting device LD stacked in a direction away from the substrate SU. The light emitting device LD may include a first electrode ANO, a light emitting layer EL, and a second electrode CAT stacked in a direction away from the substrate SU, wherein:

The substrate SU is used to support the circuit layer DL and the light emitting device LD, and it may be a flexible structure or a rigid structure.

The circuit layer DL may be disposed on a side of the substrate SU. The circuit layer DL is used to drive the light emitting device LD to emit light and has a driving circuit for driving the light emitting device LD to emit light. The driving circuit may include a pixel circuit and a peripheral circuit, wherein:

The pixel circuit may be a 3TIC, 7TIC or other pixel circuits, and nTmC indicates that a pixel circuit includes n transistors (indicated by the letter “T”) and m capacitors (indicated by the letter“C”). The number of pixel circuits may be multiple, and may be arranged in the array of multiple rows and columns. A pixel circuit may be connected to a first electrode ANO of a light emitting device LD and may receive a first power supply signal. Of course, there may also be a situation where a pixel circuit is connected to multiple light emitting devices LD. This article only takes the one-to-one connection between the pixel circuit and the light emitting device LD as an example for explanation.

The peripheral circuit can be connected to the light emitting device LD through the pixel circuit on the one hand, and can be connected to the second electrode CAT of the light emitting device LD on the other hand, and apply a second power supply signal to the second electrode CAT, and can control the current passing through the light emitting device LD by controlling the pixel circuit, thereby controlling the brightness of the light emitting device LD. The peripheral circuit may include a gate drive circuit, and may also include a light emitting control circuit, etc.

For example, the gate drive circuit may include multiple cascaded gate shift register units, which may provide reset control signals and scan signals for multiple rows of pixel circuits, thereby controlling the sequential turning on of transistors. For example, a gate shift register unit may include multiple transistors and capacitors, which may be 8T2C, 10T2C or 12T2C, etc. nTmC means that a pixel circuit includes n transistors (represented by the letter “T”) and m capacitors (represented by the letter “C”), and its specific structure is not specifically limited here. The light-emitting control circuit may include multiple cascaded light-emitting shift register units, and the specific principle can be referred to the gate drive circuit, which will not be described in detail here.

As shown in FIG. 1, in some embodiments of the present disclosure, in order to facilitate signal transmission, the display panel may include a reset control line, a scan line, a light control line, a reset signal line, a data line DAL, and a power line, etc., wherein the reset control line, the scan line, the light control line, and the reset signal line all pass through the display area AA along the row direction X and extend into the peripheral area WA; the data line and the power line all pass through the display area AA along the column direction Y and extend into the peripheral area WA, and the data line DAL is connected to the binding part PA, or may also be connected to the driving chip. The scan line and the reset control line may be connected to the gate driving circuit, and the light control line may be connected to the light control circuit.

A column of pixel circuits is connected to at least one data line DAL and a power line, and is connected to at least one reset control line, at least one scan line, at least one light-emitting control line, and at least one reset signal line. The reset signal line is used to transmit a reset signal, the data line DAL is used to transmit a data signal for controlling the brightness of the light-emitting device LD, and the power line is used to transmit a first power signal; the reset control line is used to control the writing timing of the reset signal, the scan line is used to control the writing timing of the data signal, and the light-emitting control line is used to control the light-emitting timing of the light-emitting device LD.

At the same time, the display panel may also include a plurality of buses BL, which may extend from the peripheral area WA to the lead-out area FA and be connected to the binding portion PA, and of course, may also be connected to the driver chip. The buses may include a reset signal bus, a first power bus, and a second power bus. The reset signal line may be connected to the reset signal bus, and a reset signal may be transmitted to the reset signal line through the reset signal bus. The power line may be connected to the first power bus for transmitting a first power signal, and the second electrode CAT of each light-emitting device LD may be connected to the second power bus for transmitting a second power signal.

In addition, the display panel may further include a driving line, including a driving power line, a trigger signal line, and a clock signal line connected to the gate shift register unit. For example, the driving power line includes a first driving power line and a second driving power line for providing power to the gate shift register unit, and the trigger signal line is used to provide the above-mentioned trigger signal. The clock signal line may include a first clock signal line and a second clock signal line, which are used to control the conduction timing of at least part of the transistors.

Hereinafter, the stacked structure of the circuit layer DL is exemplified below by taking the transistors of the pixel circuit using polysilicon transistors as an example:

As shown in FIG. 3 and FIG. 11 to FIG. 14, the circuit layer DL may include a circuit blocking layer BAR2, a buffer layer BUF, a semiconductor layer POL, a first gate insulating layer GI1, a first gate layer GA1, a second gate insulating layer GI2, a second gate layer GA2, an interlayer dielectric layer ILD, a first source and drain layer SD1, a passivation layer PVX, a first planar layer PLN1, a second source and drain layer SD2, and a second planar layer PLN2, which are sequentially stacked in a direction away from the substrate SU, wherein:

The circuit blocking layer BAR2 may cover a side of the substrate SU. The buffer layer BUF may cover the circuit blocking layer BAR2. The materials of the circuit blocking layer BAR2 and the buffer layer BUF may be inorganic insulating materials such as silicon nitride, silicon oxide, and the like. The circuit blocking layer BAR2 and the buffer layer BUF may prevent the impurities of the substrate SU from affecting the formation of the semiconductor layer POL and the operation of the driving circuit.

The first semiconductor layer POL may be disposed on the surface of the buffer layer BUF away from the substrate SU, and include the channel of the transistor in the driving circuit. The material of the semiconductor layer POL may be polysilicon. The first gate insulating layer GI1 may cover the semiconductor layer POL, and the material of the first gate insulating layer GI1 may be an inorganic insulating material such as silicon nitride, silicon oxide, and the like. The first gate layer GA1 may be disposed on the surface of the first gate insulating layer GII away from the substrate SU, and overlap with the semiconductor layer POL, thereby forming each transistor of the driving circuit, and the region where the first gate layer GA1 overlaps with the semiconductor layer POL is the gate of the transistor, and the first gate layer GA1 may also include the first electrode plate of the capacitor. The material of the first gate layer GA1 may include metals such as molybdenum or conductive metal oxides, etc. The second gate insulating layer GI2 may cover the first gate layer GA1, and the material thereof may be an inorganic insulating material such as silicon nitride, silicon oxide, and the like.

The second gate layer GA2 may be disposed on a surface of the second gate insulating layer GI2 away from the substrate SU, and include a second electrode plate of the capacitor, and the second electrode plate overlaps with the first electrode plate to form a capacitor.

The interlayer dielectric layer ILD may cover the second gate layer GA2, and its material may include inorganic insulating materials such as silicon nitride, silicon oxide, and the like. The first source and drain layer SD1 may be arranged on the surface of the interlayer dielectric layer ILD away from the substrate SU. The first source and drain layer SD1 may be used to achieve connections between transistors and between transistors and capacitors. The specific pattern is not specifically limited here. The passivation layer PVX may cover the first source and drain layer SD1, and its material may include inorganic insulating materials such as silicon nitride, silicon oxide, and the like. The first planar layer PLN1 may cover the passivation layer PVX, and its material may be an insulating material such as resin. The second source and drain layer SD2 may be arranged on the surface of the first planar layer PLN1 away from the substrate SU, and may include the above-mentioned data line DAL and power line, and may also be used to achieve connections between transistors and between transistors and capacitors. The specific pattern is not specifically limited here. The second planar layer PLN2 may cover the second source and drain layer SD2, and its material may be an insulating material such as resin.

As shown in FIG. 3 and FIG. 11 to FIG. 14, there are multiple light-emitting devices LD, and they can be arranged on the side of the circuit layer DL away from the substrate SU. For example, the light-emitting device LD can be arranged on the surface of the second planar layer PLN2 away from the substrate SU. Each light-emitting device LD is located in the display area AA, so that the entire display area AA can emit light. At the same time, the light-emitting device LD can be an organic light-emitting diode (OLED), of course, it can also be a Micro LED (micrometer light-emitting diode) and Mini LED (sub-millimeter light-emitting diode), and it can also be a light-emitting device such as QLED (quantum dot diode).

In some embodiments of the present disclosure, the light emitting device LD may include a first electrode ANO, a light emitting layer EL, and a second electrode CAT stacked in a direction away from the substrate SU, wherein:

As shown in FIG. 3 and FIG. 11 to FIG. 14, the first electrode ANO may be arranged on the side of the circuit layer DL away from the substrate SU and distributed in an array. For example, the first electrode ANO may be arranged on the surface of the second planar layer PLN2 away from the substrate SU. The light-emitting layer EL may include a hole injection layer, a hole transport layer, a light-emitting material layer, an electron transport layer and an electron injection layer stacked in a direction away from the substrate SU, and the specific materials thereof are not specifically limited herein. Each light-emitting device LD may share the second electrode CAT, that is, the second electrode CAT may be a continuous whole-layer structure, and the second electrode CAT may extend to the peripheral area WA and be connected to the second power bus. The first electrode ANO is distributed in an array in the display area AA and is connected to the pixel circuit, and each light-emitting device LD may emit light independently.

In addition, as shown in FIG. 3 and FIG. 11 to FIG. 14, in order to limit the light-emitting range of the light-emitting device LD and prevent crosstalk, a pixel definition layer PDL may be provided on the surface where the first electrode ANO is provided, and the pixel definition layer PDL may be provided with an opening to expose each first electrode ANO, and the light-emitting layer EL is stacked with the first electrode ANO in the opening. For example, the pixel definition layer PDL and the first electrode ANO are both provided on the surface of the second planar layer PLN2 away from the substrate SU. In addition, the opening of the pixel definition layer PDL may be smaller than the first electrode ANO exposed therein.

In some embodiments of the present disclosure, each light emitting device LD may share a light emitting layer EL, so that each light emitting device LD has the same light emitting color. In this case, in order to achieve color display, a color filter layer may be provided on the side of the light emitting device LD away from the substrate SU. The color filter layer has a filter portion corresponding to each light emitting device LD. At least a portion of the filter portion may only transmit monochromatic light, or a transparent filter portion may exist. After the light emitted by each light emitting device LD passes through the corresponding filter portion, colored light may be obtained to achieve color display. The specific principle will not be described in detail here.

Of course, in other embodiments of the present disclosure, in the light-emitting layer EL of each light-emitting device LD, at least the light-emitting material layer may include light-emitting units arrayed in each opening, so that one light-emitting device LD can independently emit monochromatic light. Of course, the light-emitting layer EL can be divided into a plurality of light-emitting structures distributed at intervals, and one light-emitting structure is arranged in an opening of the pixel definition layer PDL, so that each light-emitting device LD can directly emit monochromatic light.

Furthermore, the display panel of the present disclosure may further include an encapsulation layer, which may cover each light emitting device LD and is used to protect the light emitting device LD. For example, the encapsulation layer may be encapsulated in a thin film manner, and the encapsulation layer may include a first inorganic layer, an organic layer, and a second inorganic layer, wherein:

The first inorganic layer may cover each light emitting device LD, that is, the first inorganic layer may cover the surface of the second electrode CAT away from the substrate SU.

The organic layer may be disposed on the surface of the first inorganic layer away from the substrate SU, and the boundary of the organic layer may be limited inside the boundary of the first inorganic layer by the barrier dam located in the peripheral area WA. The material of the organic layer may be organic material such as resin.

The second inorganic layer may cover the organic layer and the first inorganic layer not covered by the organic layer, and the second inorganic layer may be used to block the intrusion of water and oxygen, and the organic layer having fluidity (during the manufacturing process) may be used to achieve planarization.

In addition, the display panel may further include other film layers such as a touch layer and a transparent cover plate which are arranged on a side of the encapsulation layer away from the substrate SU, which will not be described in detail here.

At least part of the various wirings of the above-mentioned display panel, such as the data line DAL, the first power bus, the second power bus, the reset signal bus, the driving power line, the trigger signal line and the clock signal line, etc., need to be extended into the lead-out area FA, and can be connected to the binding part PA, so as to be connected to the control circuit board through the flexible circuit board, and can also be connected to the driving chip. This part of the wirings is concentrated in the peripheral area WA corresponding to the lead-out area FA and extends into the lead-out area FA. In order to avoid short circuit, the peripheral area WA at this position needs to have a certain width to accommodate these routing lines, but this is not conducive to increasing the screen-to-body ratio of the display panel. For the convenience of description, the width can be defined as the width of the lower frame of the display panel, and the routing lines that need to extend from the peripheral area WA to the lead-out area FA are defined as signal lines PL. Any signal line PL can be located in any one or more conductive film layers in the display panel. For example, any signal line PL can be located in the above-mentioned first gate layer GA1, the second gate layer GA2, the first source and drain layer SD1 or the second source and drain layer SD2, and the film layers where different signal lines PL are located can be different.

As shown in FIG. 1, in order to reduce the width of the lower frame without affecting signal transmission, a transfer line CL can be provided in the substrate SU. The transfer line CL can extend through the peripheral area WA to the lead-out area FA and be connected to the binding part PA, that is, connected to the pin of the binding part PA. Of course, the transfer line CL can also be connected to the driver chip. In addition, the transfer line CL can extend to the display area AA. The implementation is described in detail hereinafter.

As shown in FIG. 3 and FIG. 11 to FIG. 14, for the convenience of description, the respective film layers of the circuit layer DL can be classified into an opening layer TL and a filling layer PL stacked in sequence in a direction away from the substrate SU, and the signal line PL can be located on the surface of the opening layer TL away from the substrate SU. For example:

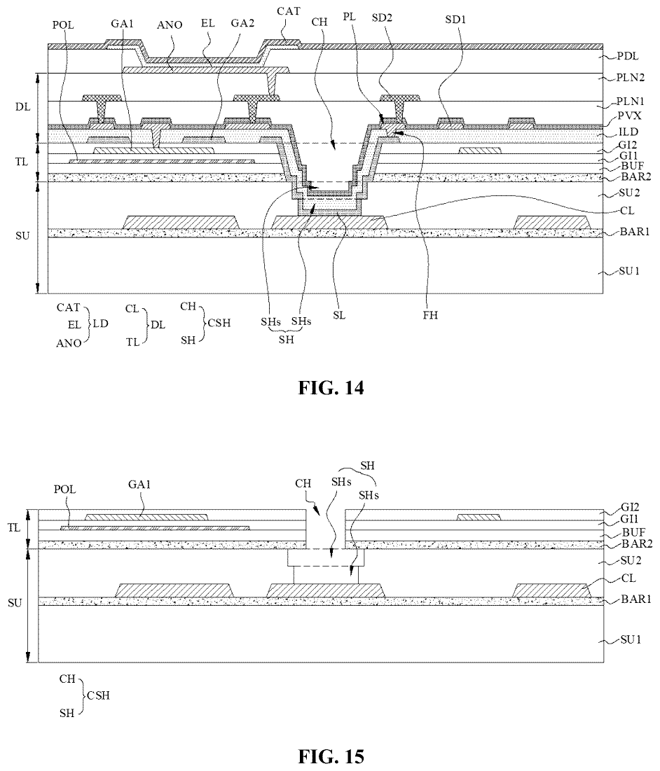

As shown in FIG. 3 and FIG. 14, in the first type of implementation of the present disclosure, the opening layer TL may include a circuit blocking layer BAR2, a buffer layer BUF, a semiconductor layer POL, a first gate insulating layer GI1, a first gate layer GA1, and a second gate insulating layer GI2. The filling layer PL may include a second gate layer GA2, an interlayer dielectric layer ILD, a first source and drain layer SD1, a passivation layer PVX, a first planar layer PLN1, a second source and drain layer SD2, and a second planar layer PLN2. The signal line PL may be located in the second gate layer GA2, that is, the signal line PL may be arranged in the same layer as the second electrode plate of the capacitor.

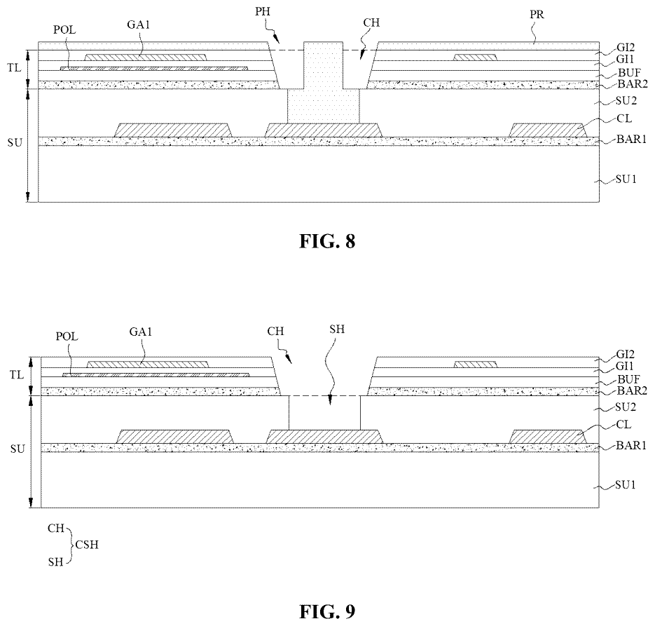

As shown in FIG. 11, in the second type of implementation of the present disclosure, the opening layer TL may include a circuit blocking layer BAR2, a buffer layer BUF, a semiconductor layer POL and a first gate insulating layer GI1. The filling layer PL may include a first gate layer GA1, a second gate insulating layer GI2, a second gate layer GA2, an interlayer dielectric layer ILD, a first source and drain layer SD1, a passivation layer PVX, a first planar layer PLN1, a second source and drain layer SD2 and a second planar layer PLN2. The signal line PL may be located in the first gate layer GA1, that is, the signal line PL may be arranged in the same layer as the gate of the transistor.

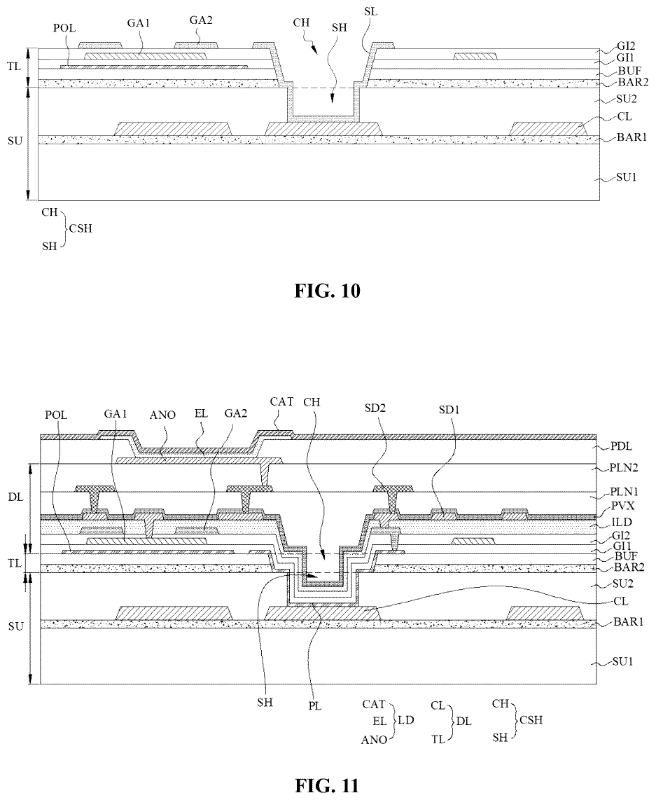

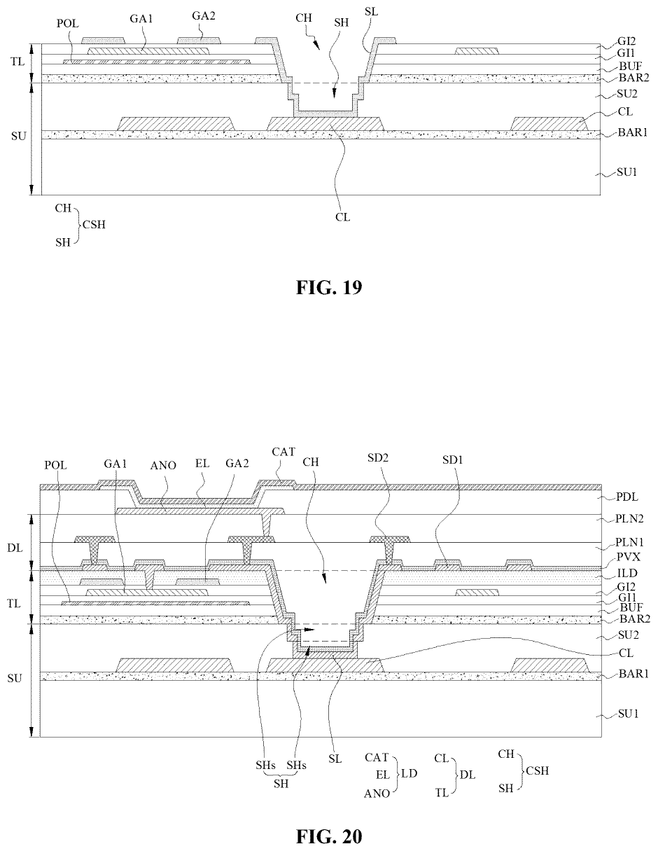

As shown in FIG. 12 and FIG. 20 to FIG. 23, in the third type of implementation of the present disclosure, the opening layer TL may include a circuit blocking layer BAR2, a buffer layer BUF, a semiconductor layer POL, a first gate insulating layer GI1, a first gate layer GA1, a second gate insulating layer GI2, a second gate layer GA2 and an interlayer dielectric layer ILD. The filling layer PL may include a first source and drain layer SD1, a passivation layer PVX, a first planar layer PLN1, a second source and drain layer SD2 and a second planar layer PLN2. The signal line PL may be located in the first source and drain layer SD1.

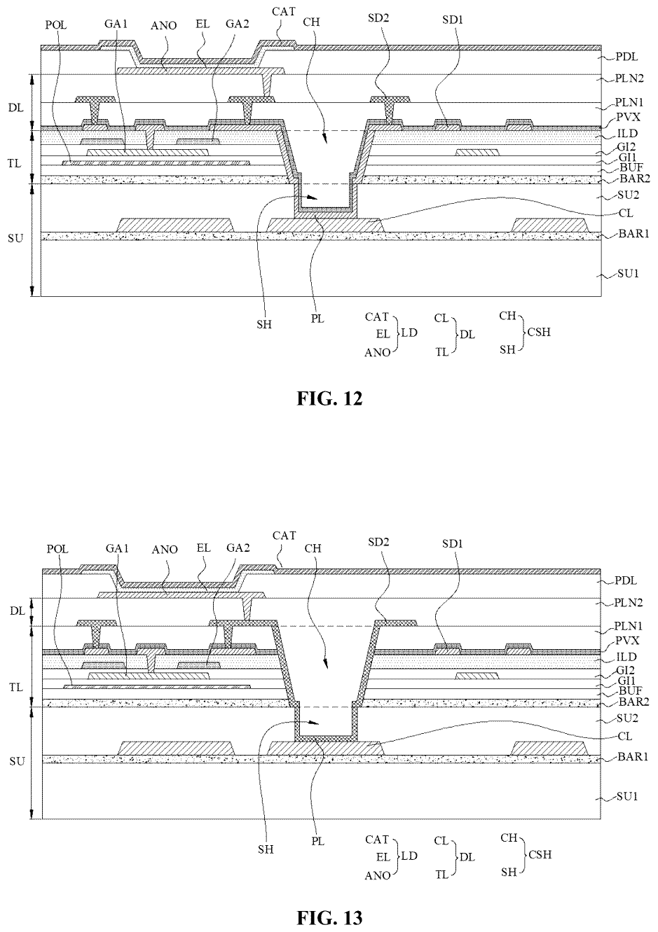

As shown in FIG. 13, in the fourth type of implementation of the present disclosure, the opening layer TL may include a circuit blocking layer BAR2, a buffer layer BUF, a semiconductor layer POL, a first gate insulating layer GI1, a first gate layer GA1, a second gate insulating layer GI2, a second gate layer GA2, an interlayer dielectric layer ILD, a first source and drain layer SD1, a passivation layer PVX, and a first planar layer PLN1. The filling layer PL may include a second source and drain layer SD2 and a second planar layer PLN2. The signal line PL may be located in the second source and drain layer SD2.

At least one of the peripheral area WA and the display area AA may be provided with a substrate transfer hole SH exposing the transfer line CL, and the circuit layer DL may be provided with a circuit transfer hole CH connected to the substrate transfer hole SH. The substrate transfer hole SH and the circuit transfer hole CH connected to each other may form a transfer hole CSH exposing the transfer line CL. At least a portion of the signal line PL may be connected to the transfer line CL through the transfer hole CSH. For example, at least a portion of the signal line PL may extend into the transfer hole CSH in accordance with the sidewalls of the circuit transfer hole CH and the substrate transfer hole SH, and be connected to the transfer line CL. At the same time, the transfer line CL extends into the lead-out area FA, and then is directly or indirectly connected to the binding part PA, or is connected to the driving chip, so as to make full use of the internal space of the substrate SU for wiring. When the overall size remains unchanged, the wiring space can be increased to avoid excessive concentration of the wiring in the lower frame, thereby facilitating the reduction of the width of the lower frame.

The structure of the substrate SU is described in detail below:

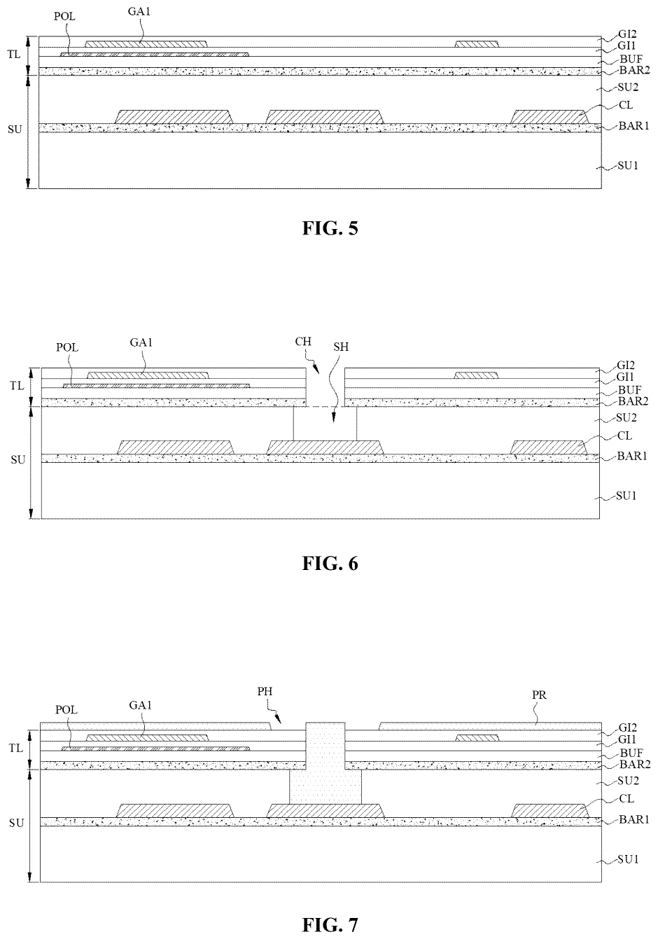

As shown in FIG. 3, FIG. 4, and FIG. 11 to FIG. 14, in some embodiments of the present disclosure, the substrate SU may include a first base SU1 and a second base SU2, wherein:

The first substrate SU1 may be a bendable flexible flat plate, and its material may include organic flexible materials such as polyimide, so that the display panel can be bent along the bending area BA. Of course, the first substrate SU1 may also be a rigid structure, and its material may be glass, etc. The transfer line CL is provided on a side of the first substrate SU1.

The second substrate SU2 may be disposed on one side of the first substrate SU1, and the circuit layer DL may be disposed on a side of the second substrate SU2 away from the first substrate SU1. For example, the circuit blocking layer BAR2 may cover a surface of the second substrate SU2 away from the first substrate SU1.

In addition, a substrate barrier layer BAR1 may be disposed between the first substrate SU1 and the second substrate SU2, and the second substrate SU2 is disposed on the surface of the substrate barrier layer BAR1 away from the first substrate SU1. The material of the substrate barrier layer BAR1 may be an inorganic insulating material such as silicon nitride, silicon oxide, and the like, and its thickness is smaller than that of the first substrate SU1 and the second substrate SU2.

The transfer line CL may be disposed between the first substrate SU1 and the second substrate SU2. For example, the transfer line CL is located on the surface of the substrate barrier layer BAR1 away from the first substrate SU1. The specific pattern thereof is not particularly limited herein.

As shown in FIG. 6, the transfer hole CSH may extend to the second substrate SU2. For example, the substrate transfer hole SH may be provided in the second substrate SU2 and penetrate the second substrate SU2 to expose the transfer line CL. The circuit transfer hole CH penetrates the opening layer TL. The specific film layer penetrated by the circuit transfer hole CH depends on the specific film layer of the opening layer TL. For example:

As shown in FIG. 3 and FIG. 14, for the first type of implementation described above, the circuit transfer hole CH may penetrate the circuit blocking layer BAR2, the buffer layer BUF, the first gate insulating layer GI1 and the second gate insulating layer GI2.

As shown in FIG. 11, for the second type of implementation, the circuit transfer hole CH may penetrate the circuit blocking layer BAR2, the buffer layer BUF and the first gate insulating layer GI1.

As shown in FIG. 12 and FIG. 20 to FIG. 22, for the third type of implementation, the circuit transfer hole CH may penetrate the circuit blocking layer BAR2, the buffer layer BUF, the semiconductor layer POL, the first gate insulating layer GI1, the first gate layer GA1, the second gate insulating layer GI2, the second gate layer GA2 and the interlayer dielectric layer ILD.

As shown in FIG. 13, for the fourth type of implementation, the circuit transfer hole CH may penetrate the circuit blocking layer BAR2, the buffer layer BUF, the semiconductor layer POL, the first gate insulating layer GI1, the first gate layer GA1, the second gate insulating layer GI2, the second gate layer GA2, the interlayer dielectric layer ILD, the passivation layer PVX and the first planar layer PLN1.

The filling layer PL can fill the circuit transfer hole CH and include the signal line PL. For example, for the first type of implementation, the interlayer dielectric layer ILD and the passivation layer PVX are recessed at the circuit transfer hole CH, and the recessed area covers the signal line PL, and the first planar layer PLN1 fills the recessed area. The structures of the second to fourth types of implementations can refer to the first type of implementation, and will not be described in detail here.

Hereinafter, the substrate transfer hole SH and the circuit transfer hole CH are described in detail.

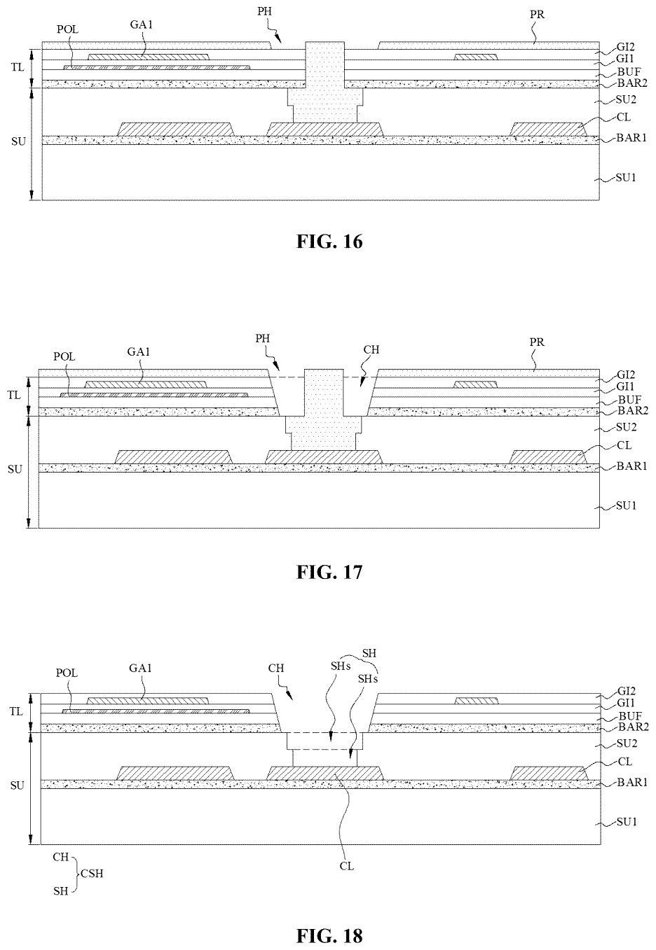

As shown in FIG. 6, FIG. 9, FIG. 15 and FIG. 18, the orthographic projection of the side wall of the circuit transfer hole CH on the substrate SU may be located outside the side wall of the substrate transfer hole SH connected to the circuit transfer hole CH, that is, the boundary of the circuit transfer hole CH is larger than the substrate transfer hole SH connected to the circuit transfer hole CH. For example, the orthographic projection of the side wall of the circuit transfer hole CH on the first substrate SU1 surrounds the orthographic projection on the first substrate SU1 of the side wall of the substrate transfer hole SH connected to the circuit transfer hole CH, thereby exposing a portion of the second substrate SU2.

The sidewall of the circuit transfer hole CH may be a slope expending in a direction away from the substrate SU, and the cross-section thereof in a direction perpendicular to the substrate SU may be in an inverted trapezoidal shape. Of course, it may also be completely or partially perpendicular to the first base SU. For example:

FIG. 21 and FIG. 22, in some embodiments of the present disclosure, the circuit transfer hole CH includes a plurality of circuit hole segments CHs that penetrate along the thickness direction of the substrate SU; in two adjacent circuit hole segments CHs, the side wall of the circuit hole segment CH away from the substrate SU is located outside the side wall of the circuit hole segment CH close to the substrate SU, that is, each circuit hole segment CHs increases in the direction away from the substrate SU. Further, if the number of the circuit hole segments CHs is two, the circuit hole segment CHs close to the substrate SU can penetrate the circuit blocking layer BAR2 and the buffer layer BUF, and the circuit hole segment CHs away from the substrate SU penetrates the first gate insulating layer GII to the interlayer dielectric layer ILD. The circuit hole segment CHs can be a straight hole or a tapered hole, etc., and its shape is not particularly limited here.

The sidewalls of the substrate transfer hole SH may be slopes that expand in a direction away from the substrate SU, and of course, may also be perpendicular to the first base SU.

It should be noted that the above-mentioned descriptions such as vertical and inverted trapezoid are not limited to absolute geometric concepts. Those skilled in the art know that due to the limitations of manufacturing and processing technology, there may be certain errors, but they still conform to the descriptions such as vertical and inverted trapezoid.

As shown in FIG. 3, FIG. 6 and FIG. 9, in some embodiments of the present disclosure, the shape of the cross-section of the side wall of the substrate transfer hole SH along the direction perpendicular to the substrate SU is a rectangle, that is, the substrate transfer hole SH is a straight hole; or, the shape of the cross-section of the side wall of the substrate transfer hole SH along the direction perpendicular to the substrate SU is an inverted trapezoid, that is, the substrate transfer hole SH is a conical hole.

As shown in FIG. 14, FIG. 15 and FIG. 18, in some embodiments of the present disclosure, the substrate transfer hole SH may be a stepped hole, which may include a plurality of substrate hole segments SHs that penetrate along the thickness direction of the substrate SU, and any substrate hole segment SH may be a straight hole or a tapered hole. At the same time, in two adjacent substrate hole segments SHs, the side wall of the substrate hole segment SH close to the circuit layer DL is located outside the side wall of the substrate hole segment SH away from the circuit layer DL, that is, the size of each substrate hole segment SHs decreases in the direction away from the circuit layer DL. Thereby, the side wall of the substrate transfer hole SH can be divided into a plurality of non-coplanar surfaces, reducing the risk of the signal line PL breaking on its side wall. Furthermore, the number of substrate hole segments SHs may be two, and the depths of the two substrate hole segments SHs are the same.

In some embodiments of the present disclosure, the circuit transfer hole CH and the substrate transfer hole SH may simultaneously adopt the above-mentioned multiple hole segment structure, or only one of them may adopt the multiple hole segment structure.

In some embodiments of the present disclosure, the signal line PL may be located on the surface of the opening layer TL away from the substrate SU, and may extend directly into the transfer hole CSH (i.e., the circuit transfer hole CH and the substrate transfer hole SH that are connected to each other), thereby directly connecting to the transfer line CL. In some embodiments of the present disclosure, a connecting lead SL may be provided between the signal line PL and the opening layer TL. The connecting lead SL may be located on the surface of the opening layer TL away from the substrate SU, and may extend directly into the transfer hole CSH. The signal line PL may be connected to the connecting lead SL through the transfer hole, thereby indirectly connecting to the transfer line CL. In addition, in other embodiments of the present disclosure, the above-mentioned direct and indirect connection methods may exist at the same time. Of course, multiple layers of connecting leads SL may also be provided between the signal line PL and the substrate SU, and two adjacent layers of connecting leads SL may be connected through the transfer hole, as long as the signal line PL and the transfer line CL can be connected.

Hereinafter, the third type of implementation is taken as an example for illustrative description.

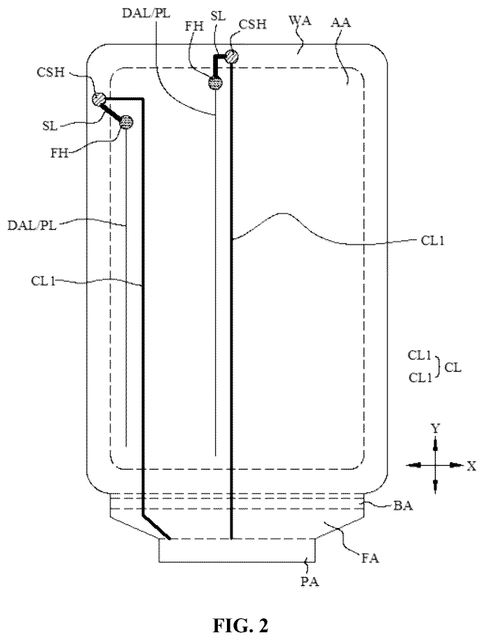

As shown in FIG. 2, at least part of the signal line PL is located in the first source-drain layer SD1, for example, the data line DAL is located in the first source-drain layer SD1, and the data line DAL is located in the display area AA and extends along the column direction Y. The transfer line CL may include a data transfer line CL1; the circuit layer DL further includes a connection lead SL extending from the display area AA to the peripheral area WA.

One end of the data transfer line CL1 is located in the peripheral area WA, and is connected to one end of a connecting lead SL located in the peripheral area WA through a transfer hole CSH; the other end of the data transfer line CL1 extends to the lead-out area FA, and is connected to the binding part PA, and can also be connected to the driving chip; one end of the connecting lead SL located in the display area AA is connected to the data line DAL through the display transfer hole FH located in the display area AA, so that the data transfer line CL1, the transfer hole CSH, the connecting lead SL, the display transfer hole FH and the data line DAL can be connected in sequence to realize the input of the data signal, without densely connecting the data line DAL to the lead-out area FA in the area where the peripheral area WA and the lead-out area FA are connected.

As shown in FIG. 3 and FIG. 14, the connecting lead SL is located between the data line DAL and the substrate SU. By connecting the data transfer line CL1 and the data line DAL through the connecting lead SL, it can avoid etching holes with larger depth at one time, thus reducing the difficulty of the process. In the embodiment, the transfer hole CSH can be etched in multiple times, and the display transfer hole FH only needs to penetrate the film layer where the connecting lead SL is located between the data lines DAL. For example, the data line DAL, as a signal line PL, can be located in the first source and drain layer SD1, and the connecting lead SL can be located in the second gate layer GA2 and extend into the transfer hole CSH. Correspondingly, the display transfer hole FH penetrates the first planar layer PLN1 and the passivation layer PVX.

The present disclosure also provides a method for manufacturing a display panel, which may be a display panel of any of the above embodiments, and will not be described in detail here. The manufacturing method may include steps S110 to S160, wherein:
Step S110: forming a substrate with a transfer line, wherein the transfer line extends from the peripheral region to the lead-out region.
Step S120: forming an opening layer on a side of the substrate.
Step S130, forming a circuit transfer hole in the opening layer, and forming a substrate transfer hole in the substrate to expose the transfer line, the circuit transfer hole is connected to the substrate transfer hole; the circuit transfer hole is located in at least one of the peripheral area and the display area; the orthographic projection of the side wall of the circuit transfer hole on the substrate is located on the inner side of the side wall of the substrate transfer hole connected to the circuit transfer hole.
Step S140, enlarging the circuit transfer hole so that the side wall of the substrate transfer hole is located within the range encircled by the orthographic projection on the substrate of the side wall of the circuit transfer hole connected to the substrate transfer hole.
Step S150, forming a filling layer covering the opening layer and filling the circuit transfer hole and the substrate transfer hole; the filling layer includes a signal line extending into the circuit transfer hole and the substrate transfer hole and connected to the transfer line.
Step S160: forming a plurality of light emitting devices located in the display area on a side of the filling layer away from the substrate.

The steps of the manufacturing method disclosed in the present invention are described in detail below.

As shown in FIG. 4, in step S110, the structure of the substrate SU can refer to the substrate SU in the above embodiment of the display panel, and will not be described in detail here. Take the substrate SU including the first base SU1, the substrate barrier layer BAR1 and the second base SU2 as an example:

As shown in FIG. 4, step S110 may include steps S1110 to S1140, wherein: Step S1110: forming a first substrate.

The first substrate SU1 may be a bendable flexible flat plate, and its material may include organic flexible materials such as polyimide, so that the display panel can be bent along the bending area BA. Of course, the first substrate SU1 may also be a rigid structure, and its material may be glass or the like.

Step S1120: forming a substrate barrier layer covering the first substrate.

The substrate barrier layer BAR1 may be made of inorganic insulating materials such as silicon nitride, silicon oxide, and the like, and its thickness is smaller than the first substrate SU1. The inorganic insulating material may be deposited on the surface of the first substrate SU1 by chemical vapor deposition to form the substrate barrier layer BAR1.

Step S1130: forming a transfer line on one side of the first substrate.

The transfer line CL is located on the surface of the substrate barrier layer BAR1 away from the first base SU1, and its specific pattern is not particularly limited herein. The transfer line CL can be made of metal or other conductive materials.

Step S1140: forming a second substrate on a side of the transfer line away from the first substrate.

The second substrate SU2 may be a bendable flexible flat plate, and its material may include organic flexible materials such as polyimide, so that the display panel can be bent along the bending area BA. Of course, the second substrate SU2 may also be a rigid structure, and its material may be glass, etc. The material of the second substrate SU2 may be the same as that of the first substrate SU1.

In step S120, the specific film layer of the opening layer TL may refer to the opening layer TL in the above embodiment of the display panel, which will not be described in detail here.

As shown in FIG. 5, in the first type of implementation of the present disclosure, the opening layer TL may include a circuit blocking layer BAR2, a buffer layer BUF, a semiconductor layer POL, a first gate insulating layer GI1, a first gate layer GA1, and a second gate insulating layer GI2. Accordingly, step S120 may include: stacking the circuit blocking layer BAR2, the buffer layer BUF, the semiconductor layer POL, the first gate insulating layer GI1, the first gate layer GA1, and the second gate insulating layer GI2 in sequence on a side of the second substrate SU2 away from the first substrate SU1, wherein the circuit blocking layer BAR2, the buffer layer BUF, the first gate insulating layer GI1, and the second gate insulating layer GI2 may all be continuous whole-layer structures, and may all be made of inorganic insulating materials, and may be formed by processes such as chemical vapor deposition; whereas the semiconductor layer POL and the first gate layer GA1 need to be patterned by means of a mask through a photolithography process or the like.

In the second to fourth types of implementation of the present disclosure, the film layer included in the opening layer TL is different from that in the first type of implementation, and thus the structure obtained after executing step S120 is also different, depending on the function of the structure, which will not be described in detail here.

As shown in FIG. 6, in step S130, in some embodiments of the present disclosure, dry etching may be used to form the circuit transfer hole CH and the substrate transfer hole SH; and the step S130 may include step S1310 and step S1320, wherein:

Step S1310: forming a circuit transfer hole in the opening layer; the circuit transfer hole is located in at least one of the peripheral area and the display area.

As shown in FIG. 6, for the first type of implementation, the area where the circuit transfer hole CH needs to be formed does not have the semiconductor layer POL and the first gate layer GA1, but the circuit blocking layer BAR2, the buffer layer BUF, the first gate insulating layer GI1 and the second gate insulating layer GI2 are stacked in sequence. In order to facilitate the opening, the circuit blocking layer BAR2, the buffer layer BUF, the first gate insulating layer GI1 and the second gate insulating layer GI2 can be made of the same material, and the circuit transfer hole CH penetrating the circuit blocking layer BAR2, the buffer layer BUF, the first gate insulating layer GI1 and the second gate insulating layer GI2 can be formed by dry etching. The circuit transfer hole CH can expose the substrate SU, for example, the circuit transfer hole CH exposes the surface of the second substrate SU2 away from the first substrate SU1.

For the second to fourth types of implementation, the shape of the circuit transfer hole CH can refer to the first type of implementation, as long as the substrate SU can be exposed through the circuit transfer hole CH.

The sidewalls of the circuit transfer hole CH may be slopes that expand in a direction away from the substrate SU, and the shape of the cross section thereof in a direction perpendicular to the substrate SU may be an inverted trapezoid.

Step S1320, using the opening layer as a mask, etching the substrate along the circuit transfer hole to form a substrate transfer hole exposing the transfer line; the orthographic projection of the side wall of the circuit transfer hole on the substrate is located inside the side wall of the substrate transfer hole connected to the circuit transfer hole.

As shown in FIG. 6, the material of the substrate SU exposed by the circuit transfer hole CH is different from the material through which the circuit transfer hole CH penetrates. The opening layer TL can be used as a hard mask to etch the substrate SU along the circuit transfer hole CH until the transfer line CL is exposed, thereby forming the substrate transfer hole SH. For example, the second substrate SU2 is etched along the circuit transfer hole CH until the transfer line CL is exposed, thereby forming the substrate transfer hole SH.

As shown in FIG. 15, in some embodiments of the present disclosure, the substrate transfer hole SH may be a stepped hole having a plurality of substrate hole segments SDs. By dividing the sidewall of the substrate transfer hole SH into the sidewalls of the plurality of substrate hole segments SHs, a large area of continuous sidewalls is avoided, thereby reducing the risk of the signal line PL being broken at the sidewall due to the difficulty of material film formation. For example, step S1320 may include:

etching the substrate SU multiple times along the circuit switching hole CH, so that the substrate switching hole SH includes multiple substrate hole segments SHs that penetrate along the thickness direction of the substrate SU; in two adjacent substrate hole segments SHs, the side wall of the substrate hole segment SHs close to the opening layer TL is located outside the side wall of the substrate hole segment SHs away from the opening layer TL.

Taking dry etching as an example, the etching depth can be controlled by controlling the flow rate of the plasma gas or the etching time, thereby forming a plurality of substrate hole segments SHs. For example, a substrate transfer hole SH exposing the transfer line CL can be formed by etching for a first time; and then etching is performed again for a second time, the second time is less than the first time, and thus the etching depth is less than the etching depth at the first time, so that the substrate transfer hole SH is partially enlarged, thereby dividing two substrate hole segments SHs, and similar process may be repeated to form a plurality of substrate hole segments SHs. The sub-pixels are very cautious and the etching may be only twice, and the second etching time can be half of the first etching time, so that the depth of the second etching is half of the depth of the first etching, thereby forming two substrate hole segments SHs with the same depth.

Of course, it is also possible to only use sequential etching to make the substrate switching hole SH a straight hole or a tapered hole.

In addition, in other embodiments of the present disclosure, the opening layer TL may not be used as a mask, but a special mask may be formed on the opening layer TL using photoresist or other etching resist materials to form the circuit transfer holes CH and the substrate transfer holes SH. After the circuit transfer holes CH and the substrate transfer holes SH are formed, the mask is removed.

For the second substrate SU2 of the flexible structure made of organic material, the dry etching rate of the dry etching is greater than the previous etching rate of the opening layer TL, so that the substrate transfer hole SH is larger than the circuit transfer hole CH connected thereto, that is, the orthographic projection of the side wall of the circuit transfer hole CH on the substrate SU is located on the inner side of the side wall of the substrate transfer hole SH connected thereto, thereby forming a cantilever structure, which makes it difficult to form a continuous film layer and easily causes the signal line to break.

In order to solve the problem caused by the cantilever structure, the circuit transfer hole CH may be enlarged, and the opening layer TL covering the substrate transfer hole SH may be removed, so that the side wall of the substrate transfer hole SH is located within the range encircled by the orthographic projection on the substrate SU of the side wall of the circuit transfer hole CH connected thereto, that is, step S140 is performed to achieve this effect. As shown in FIG. 7 to FIG. 9, in some embodiments of the present disclosure, step S140 may include steps S1410 to S1440, wherein:

Step S1410: forming an etching resist layer covering the opening layer and filling the circuit transfer hole and the substrate transfer hole.

As shown in FIG. 7 and FIG. 16, the material of the etching resist layer PR may be photoresist, which may be coated on the surface of the opening layer TL away from the substrate SU, for example, the etching resist layer PR may be coated on the surface of the second gate insulating layer GI2 away from the substrate SU. At the same time, the etching resist layer PR also fills the substrate transfer hole SH and the circuit transfer hole CH.

Step S1420, forming an annular hole in the etching resist layer to expose the opening layer; and the part of the etching resist layer surrounded by the annular hole is filled in the circuit transfer hole and the substrate transfer hole; and the orthographic projection of the outer wall of the annular hole on the substrate is located outside the side wall of the substrate transfer hole.

As shown in FIG. 7 and FIG. 16, the etching resist layer PR can be patterned to form an annular hole PH, and the annular hole PH exposes the opening layer TL to be removed, wherein the portion of the etching resist layer PR surrounded by the annular hole PH can fill the circuit transfer hole CH and the substrate transfer hole SH. The orthographic projection of the outer wall of the annular hole PH on the substrate SU is located outside the side wall of the substrate transfer hole SH, so that the opening layer TL covering the substrate transfer hole SH is completely exposed by the annular hole PH. For the etching resist layer PR using photoresist, patterning can be achieved by exposure and development using a mask to obtain the annular hole PH.

Step S1430, etching the opening layer exposed by the annular hole so that the orthographic projection of the side wall of the circuit transfer hole on the substrate is located outside the side wall of the substrate transfer hole connected thereto.

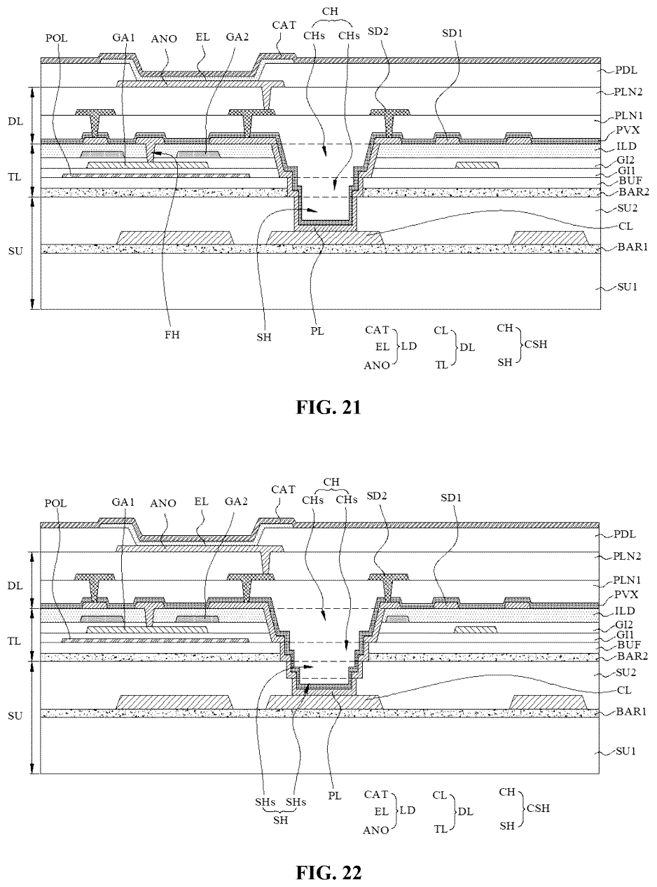

As shown in FIG. 8, FIG. 17 and FIG. 23, since the opening layer TL covering the substrate transfer hole SH is completely exposed by the annular hole PH, the opening layer TL can be etched along the annular hole PH by dry etching or other processes to remove the opening layer TL covering the substrate transfer hole SH. For example, for the first type of implementation, the circuit blocking layer BAR2, the buffer layer BUF, the first gate insulating layer GI1 and the second gate insulating layer GI2 corresponding to the annular hole PH need to be removed. The film layers to be removed for the second to fourth types of implementations depend on the film layers included in the opening layer TL. Thus, the circuit transfer hole CH can be enlarged so that the side wall of the circuit transfer hole CH is located outside the substrate transfer hole SH.

During the execution of step S1430, the etching resist layer PR always fills the substrate transfer hole SH, thereby protecting the sidewall of the substrate transfer hole SH and preventing it from expanding due to etching, thereby ensuring that the cantilever structure can be eliminated.

Step S1440: removing the etching resist layer.

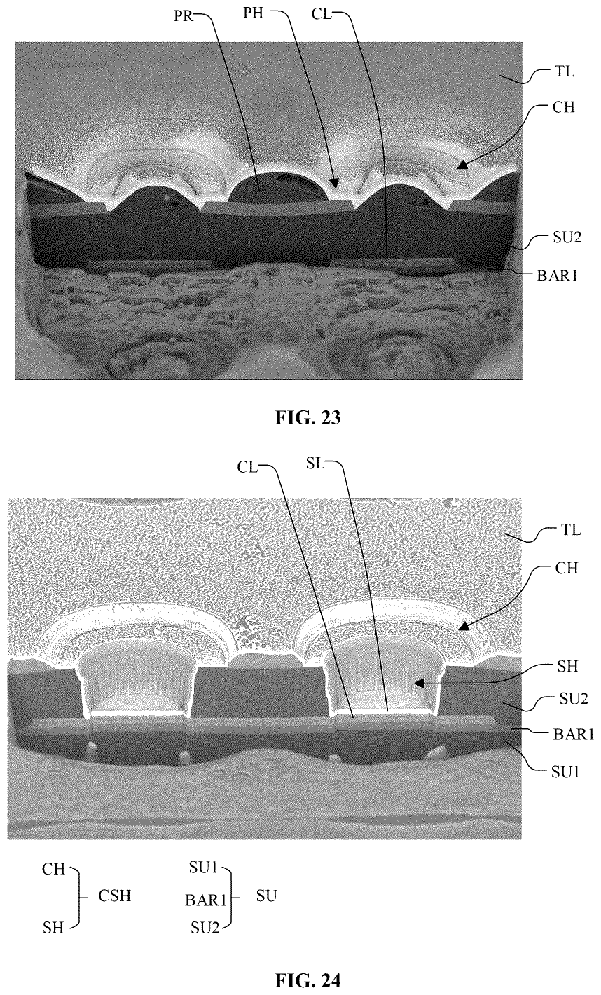

As shown in FIG. 9, FIG. 18 and FIG. 24, the etching resist layer PR may be removed by an ashing process or other processes so as to stack the filling layer PL.

In step S150, the structure of the filling layer PL may refer to the filling layer PL in the above embodiment of the display panel, and will not be described in detail here.

In the first type of implementation of the present disclosure, step S150 may include steps S1510 to S1530, wherein:

Step S1510: stacking a second gate layer, an interlayer dielectric layer, a first source and drain layer and a passivation layer in sequence on a side of the opening layer away from the first substrate, wherein the interlayer dielectric layer and the passivation layer are recessed at the circuit transfer hole; the second gate layer includes a signal line extending into the circuit transfer hole and the substrate transfer hole and connected to the transfer line.

As shown in FIG. 10 and FIG. 19, the signal line PL may be located in the second gate layer GA2, and may extend into the circuit transfer hole CH and the substrate transfer hole SH, and be connected to the transfer line CL. The thickness of the interlayer dielectric layer ILD and the passivation layer PVX is less than the depth of the circuit transfer hole CH and the substrate transfer hole SH, and they extend into the circuit transfer hole CH and the substrate transfer hole SH, and are recessed, and the recessed area covers the signal line CL.

The first source-drain layer SD1 is located on the surface of the interlayer dielectric layer ILD away from the substrate SU and outside the circuit transfer hole CH. The first source-drain layer SD1 can be made of metal or other conductive materials and can be connected to at least one transistor in the opening layer TL directly or through a part of the second gate layer GA2.

Step S1520: forming a first planar layer covering the passivation layer and filling the recessed areas of the interlayer dielectric layer and the passivation layer.

As shown in FIG. 3 and FIG. 14, the first planar layer PLN1 can fill the recessed area of the passivation layer PVX and achieve planarization to fill the recessed area. The material of the first planar layer PLN1 can be resin or other insulating materials.

Step S1530: stacking a second source-drain layer and a second planar layer in sequence on a side of the first planar layer away from the first substrate.

As shown in FIG. 3 and FIG. 14, the second source-drain layer SD2 is disposed on the surface of the first planar layer PLN1 away from the substrate SU and outside the circuit transfer hole CH. The second source-drain layer SD2 can be made of metal or other conductive materials and can be connected to at least one transistor in the opening layer TL. The second planar layer PLN2 can fill the recessed portion GR and realize flattening to fill the recessed portion GR. The material of the second planar layer PLN2 can be resin or other insulating materials.

In the second to fourth types of implementations, the specific steps of step S150 depend on the specific film layer of the filling layer PL. The specific principle can refer to step S150 in the first type of implementation above, wherein:

As shown in FIG. 12, the recessed area in the filling layer PL in the second type of implementation includes, in addition to the interlayer dielectric layer ILD and the passivation layer PVX, a second gate insulating layer GI2, and a first planar layer PLN1 to fill the recessed area.

As shown in FIG. 13, in the third type of implementation, the recessed area in the filling layer PL is filled with only the passivation layer PVX and the first planar layer PLN1.

As shown in FIG. 14, in the fourth type of implementation, the circuit barrier layer BAR2 to the passivation layer PVX in the filling layer PL are penetrated by the circuit transfer hole CH without being recessed, and the first planar layer PLN1 directly fills the circuit transfer hole CH and the substrate transfer hole SH.

As shown in FIG. 3 and FIG. 11 to FIG. 14, in step S160, the structure of the light emitting device LD can refer to the light emitting device LD in the embodiment of the display panel above, and will not be described in detail here. When forming the light emitting device LD, the first electrode ANO, the pixel definition layer PDL, the light emitting layer EL and the second electrode CAT can be formed in sequence, and the specific process is not particularly limited here.

In addition, the manufacturing method of the present disclosure may further include steps such as forming an encapsulation layer covering the light-emitting device.

It should be noted that, although the steps of the manufacturing method in the present disclosure are described in a specific order in the drawings, this does not require or imply that the steps must be performed in this specific order, or that all the steps shown must be performed to achieve the desired results. Additionally or alternatively, some steps may be omitted, multiple steps may be combined into one step, and/or one step may be decomposed into multiple steps, etc.

The present disclosure also provides a display device, which may include a display panel of any of the above embodiments. The display panel is a display panel of any of the above embodiments, and its specific structure and beneficial effects can be referred to the embodiments of the display panel above, which will not be repeated here. The display device of the present disclosure can be a mobile phone, a smart watch, a smart bracelet, a tablet computer, a TV, and other electronic devices with display functions, which will not be listed one by one here.

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

1. A display panel comprising a display area, a peripheral area outside the display area, and a lead-out area outside the peripheral area; and the display panel comprising:
a substrate, comprising a transfer line and a substrate transfer hole exposing the transfer line, wherein the transfer line is extended to the lead-out area through the peripheral area; at least one of the peripheral area and the display area is provided with the substrate transfer hole;
a circuit layer, disposed on a side of the substrate and comprises a circuit transfer hole connected to the substrate transfer hole, and an orthographic projection of a side wall of the circuit transfer hole on the substrate is located outside a side wall of the substrate transfer hole connected to the circuit transfer hole; the circuit layer comprises a signal line, and at least part of the signal line is connected to the transfer line through the circuit transfer hole and the substrate transfer hole; and
a plurality of light emitting devices, disposed on a side of the circuit layer away from the substrate and located in the display area.

2. The display panel according to claim 1, wherein the substrate comprises:
a first substrate, wherein the transfer line is disposed on a side of the first substrate; and
a second substrate, disposed on a side of the transfer line away from the first substrate;
the substrate transfer hole is disposed in the second substrate; and the circuit layer is disposed on a side of the second substrate away from the first substrate.

3. The display panel according to claim 2, wherein the circuit layer comprises an opening layer and a filling layer stacked in sequence in a direction away from the first substrate, the circuit transfer hole is formed through the opening layer; and the filling layer comprises at least part of the signal line.

4. The display panel according to claim 3, wherein the opening layer comprises a circuit blocking layer, a buffer layer, a semiconductor layer, a first gate insulating layer, a first gate electrode layer and a second gate insulating layer stacked in sequence in a direction away from the first substrate;
the filling layer comprises a second gate layer, an interlayer dielectric layer, a first source-drain layer, a passivation layer, a first planar layer, a second source-drain layer, and a second planar layer stacked in sequence in a direction away from the first substrate; the interlayer dielectric layer and the passivation layer are recessed at the circuit transfer hole, and a recessed area is filled with the first planar layer;
the circuit transfer hole is formed through the circuit blocking layer, the buffer layer, the first gate insulating layer and the second gate insulating layer; and
the second gate layer comprises at least a portion of the signal line.

5. The display panel according to claim 1, wherein the substrate transfer hole comprises a plurality of substrate hole segments penetrating along a thickness direction of the substrate; and
in two adjacent substrate hole segments, a side wall of the substrate hole segment close to the circuit layer is located outside a side wall of the substrate hole segment away from the circuit layer.

6. The display panel according to claim 5, wherein a number of the substrate hole segments is two, and depths of the two substrate hole segments are same.

7. The display panel according to claim 1, wherein a side wall of the circuit transfer hole is a slope surface expanding in a direction away from the substrate.

8. The display panel according to claim 1, wherein the circuit transfer hole comprises a plurality of circuit hole segments penetrating along a thickness direction of the substrate; and
in two adjacent circuit hole segments, a side wall of the circuit hole segment away from the substrate is located outside a side wall of the circuit hole segment close to the substrate.

9. The display panel according to claim 4, wherein the circuit layer further comprises a connecting lead extending from the display area to the peripheral area, and the connecting lead is located between at least a portion of the signal line and the substrate; and
an end of the connecting lead located in the peripheral area is connected to at least a portion of the transfer line through the circuit transfer hole and the substrate transfer hole that are connected to each other, and an end of the connecting lead located in the display area is connected to at least a portion of the signal line through the display transfer hole located in the display area.

10. The display panel according to claim 9, wherein the signal line connected to the connecting lead is located in the first source-drain layer, and the connecting lead is located in the second gate layer; and
the display transfer hole is formed through the first planar layer and the passivation layer.

11. A manufacturing method of a display panel, the display panel comprising a display area, a peripheral area outside the display area, and a lead-out area outside the peripheral area; the manufacturing method comprising:
forming a substrate comprising a transfer line, wherein the transfer line is extended to the lead-out area through the peripheral area;
forming an opening layer on a side of the substrate;
forming a circuit transfer hole in the opening layer, and forming in the substrate a substrate transfer hole exposing the transfer line, wherein the circuit transfer hole is connected to the substrate transfer hole; the circuit transfer hole is located in at least one of the peripheral area and the display area; and an orthographic projection of a side wall of the circuit transfer hole on the substrate is located at an inner side of a side wall of the substrate transfer hole connected to the circuit transfer hole;
enlarging the circuit transfer hole so that the side wall of the substrate transfer hole is within a range encircled by the orthographic projection on the substrate of the side wall of the circuit transfer hole connected to the circuit transfer hole;
forming a filling layer covering the opening layer and filling the circuit transfer hole and the substrate transfer hole; the filling layer comprising a signal line extending into the circuit transfer hole and the substrate transfer hole and connected to the transfer line; and
forming a plurality of light emitting devices in the display area on a side of the filling layer away from the substrate.

12. The manufacturing method according to claim 11, wherein the forming the substrate comprising the transfer line comprises:
forming a first substrate;
forming the transfer line on a side of the first substrate; and
forming a second substrate on a side of the transfer line away from the first substrate.

13. The manufacturing method according to claim 11, wherein the forming the circuit transfer hole in the opening layer, and forming in the substrate the substrate transfer hole exposing the transfer line, wherein the circuit transfer hole is connected to the substrate transfer hole comprises:
forming the circuit transfer hole in the opening layer; wherein the circuit transfer hole is located in at least one of the peripheral area and the display area; and
etching, using the opening layer as mask, the substrate along the circuit transfer hole to form the substrate transfer hole exposing the transfer line; wherein the orthographic projection of the side wall of the circuit transfer hole on the substrate is located on the inner side of the side wall of the substrate transfer hole connected to the circuit transfer hole.

14. The manufacturing method according to claim 11, wherein the enlarging the circuit transfer hole comprises:
forming an etching resist layer covering the opening layer and filling the circuit transfer hole and the substrate transfer hole;
forming an annular hole in the etching resist layer to expose the opening layer, wherein a portion of the etching resist layer surrounded by the annular hole is filled in the circuit transfer hole and the substrate transfer hole; and an orthographic projection of an outer wall of the annular hole on the substrate is located outside the side wall of the substrate transfer hole;
etching the opening layer exposed by the annular hole so that the orthographic projection of the side wall of the circuit transfer hole on the substrate is outside the side wall of the substrate transfer hole connected to the circuit transfer hole; and
removing the etching resist layer.

15. The manufacturing method according to claim 12, wherein the forming the opening layer on the side of the substrate comprises:
stacking, sequentially on a side of the second substrate away from the first substrate, a circuit blocking layer, a buffer layer, a semiconductor layer, a first gate insulating layer, a first gate layer, and a second gate insulating layer;
the forming the filing layer covering the opening layer and filling the circuit transfer hole and the substrate transfer hole comprises:
stacking, sequentially on a side of the opening layer away from the first substrate, a second gate layer, an interlayer dielectric layer, a first source-drain layer and a passivation layer, wherein the interlayer dielectric layer and the passivation layer are recessed at the circuit transfer hole; and the second gate layer comprises the signal line extending into the circuit transfer hole and the substrate transfer hole and connected to the transfer line;
forming a first planar layer covering the passivation layer and filling the recessed area of the interlayer dielectric layer and the passivation layer; and
stacking, sequentially on a side of the first planar layer away from the first substrate, a second source-drain layer and a second planar layer.

16. The manufacturing method according to claim 13, wherein the etching the substrate along the circuit transfer hole to form the substrate transfer hole exposing the transfer line comprises:
etching the substrate multiple times along the circuit transfer hole so that the substrate transfer hole comprises a plurality of substrate hole segments penetrating along a thickness direction of the substrate; in two adjacent substrate hole segments, a side wall of the substrate hole segment close to the opening layer is located outside a side wall of the substrate hole segment away from the opening layer.

17. The manufacturing method according to claim 16, wherein the etching the substrate multiple times along the circuit transfer hole comprises:
etching, by a dry etching process, the substrate multiple times along the circuit transfer hole, and wherein the transfer line is exposed during a first time etching, and a depth of a subsequent etching is less than a depth of a previous etching.

18. The manufacturing method according to claim 17, wherein the substrate is etched twice, and the depth of the subsequent etching is half of the depth of the previous etching.

19. The manufacturing method according to claim 11, wherein the sidewall of the circuit transfer hole is a slope surface expanding in a direction away from the substrate.

20. A display device comprising a display panel, wherein the display panel comprises: a display area, a peripheral area outside the display area, and a lead-out area outside the peripheral area; and the display panel further comprises:
a substrate, comprising a transfer line and a substrate transfer hole exposing the transfer line, wherein the transfer line is extended to the lead-out area through the peripheral area; at least one of the peripheral area and the display area is provided with the substrate transfer hole;
a circuit layer, disposed on a side of the substrate and comprises a circuit transfer hole connected to the substrate transfer hole, and an orthographic projection of a side wall of the circuit transfer hole on the substrate is located outside a side wall of the substrate transfer hole connected to the circuit transfer hole; the circuit layer comprises a signal line, and at least part of the signal line is connected to the transfer line through the circuit transfer hole and the substrate transfer hole; and
a plurality of light emitting devices, disposed on a side of the circuit layer away from the substrate and located in the display area.
